(19) United States
(12) Patent Application Publication
(10) Pub. No.: US 2022/0281328 A1
(43) Pub. Date: Sep. 8, 2022

(54) Vehicle electrostatic propulsion system

(71) Applicant: Nathanial Henry Lewis, Fallon, NV (US)

(72) Inventor: Nathanial Henry Lewis, Fallon, NV (US)

(21) Appl. No.: 17/300,088

(22) Filed: Mar. 8, 2021

(51) Int. Cl. B60L 50/90; B60L 8/00; B60L 50/40; H01L 35/02

(52) U.S. Cl. CPC B60L 50/90; B60L 8/00; B60L 8/003; B60L 8/006; B60L 50/40; H01L 35/02

(57) ABSTRACT

The vehicle electrostatic propulsion system has two connected sections. A direct current section comprising an array of supercapacitors and an electrostatic repulsion motor; they are powered by wind and solar energies. This direct current section is connected to an alternating current section comprising a 3-phase induction generator and a 3-phase induction motor, the generator is powered by the electrostatic repulsion motor. The 3-phase induction motor power the wheels of the vehicle. The propulsion system will give a long range to a vehicle.

### BACKGROUND OF THE INVENTION

A propulsion system combining supercapacitors, an electrostatic repulsion motor, a 3-phase AC generator and a 3-phase AC motor. This combination will be powered by wind and solar energies. A 3-phase AC motor that is design for an electric vehicle, generally have a higher power-to-weight ratio, this makes them more efficient, and often require less maintenance.

An electric vehicle will have the same long range as present fossil fuel powered vehicles. The electric vehicle will also still have its present advantages over the fossil fuel vehicle.

Thomas Edison and Henry Ford built an electric car in 1912. It suffered from the need of a longer range without the need to stop to recharge its batteries. This has been the great stumbling block for the electric vehicle down through the decades.

### SUMMARY OF THE INVENTION

The Vehicle Electrostatic Propulsion System has two connected sections. A DC section comprising an array of supercapacitors and an electrostatic repulsion motor, they are powered by wind and solar energies. This DC section is connected to an AC section comprising a 3-phase induction generator and a 3-phase induction motor, the generator is powered by the electrostatic repulsion motor.

The DC section comprising the array of supercapacitors and the electrostatic repulsion motor, can be powered by a nuclear-powered battery: radioisotope thermoelectric generator. An array of supercapacitors will replace the present array of batteries.

The applications would be for many types of vehicles. They can be a car, tractor, 18-wheeler truck, Navy destroyer, train locomotive, ice breaker, propeller-driven aircraft, hydrofoil boat, bus or a submarine.

### DESCRIPTION OF DRAWINGS

FIG. 1 is a systematic—block diagram of the DC section of the vehicle propulsion system.

FIG. 2 is a perspective view of an automobile with a wind powered system and a solar powered panel.

FIG. 3 is a systematic of the arrangement of the housings of the wind powered system in front of the automobile.

FIG. 4 is a section view of a wind unit of the wind powered system.

FIG. 5 is a systematic—block diagram of the first part of the AC section of the vehicle propulsion system.

FIG. 6 is a side view of the electrostatic repulsion motor.

FIG. 7 is a block diagram showing the detail parts of a motor controller.

FIG. 8 is a systematic—block diagram of the second part of the AC section.

FIG. 9 is a side view of a submarine propeller and its induction motor of an alternate AC section.

FIG. 10 is a systematic—block diagram of an alternate DC section for submarines and other underwater vehicles and Navy ships.

### DETAILED DESCRIPTIONS

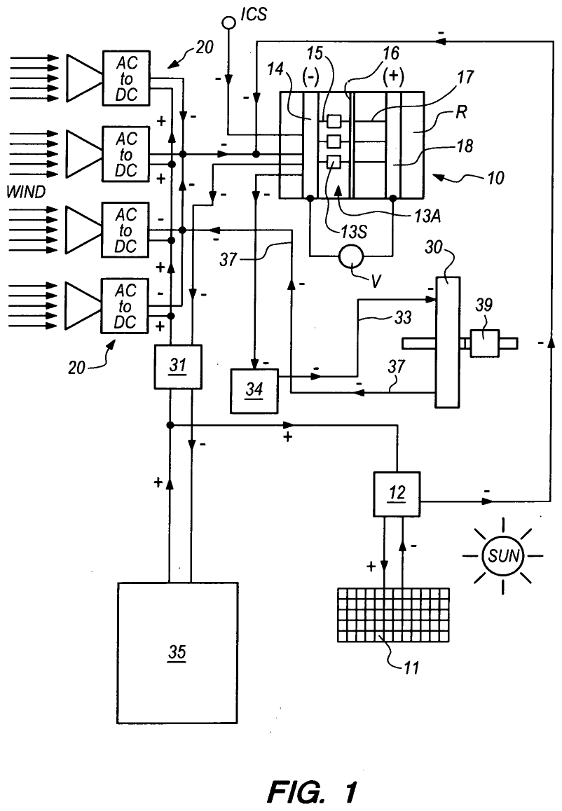

FIG.1 is the DC section of this vehicle electrostatic propulsion system. The supercapacitors system 10, an array of supercapacitors 13A on one side of an insulator 16, a line 15 of a supercapacitor 13S is connected to and can be charged by the negative electrode 14, and the other line 17 of the supercapacitor 13S passes through a hole in the insulator 16 and can be connected to the positive electrode 18. A voltmeter V would measure this array of supercapacitors 13A total voltage at all times. The reservoir R is for temporary loose charges.

For example, if we use a supercapacitor 13S that safely holds 2 volts. If we need 300 volts for our vehicle propulsion system. The number of supercapacitors 13S the array 13A would need is 150.

The wind powered system 20, an array of wind units is connected to the negative electrode 14. The negative electrode 14 is connected to a charge controller 31, this controller 31 is connected to the vehicle accessories 35. The negative electrode 14 also is connected to another charge controller 34, this controller 34 is connected to an electrostatic repulsion motor 30. This motor 30 will have a main charging line 33 and a discharging line 37 connects motor 30 to the negative electric line of a wind unit. And in some systems the motor 30 will have a speed reducer 39 attached to its axle.

A solar powered panel 11 is connected to a charge controller 12, and from controller 12 to the negative electrode 14 and to the vehicle accessories 35 return electric line (+).

If after a very, long time without driving the vehicle and the supercapacitors system 10 has no or very low energy and cannot start the vehicle. The supercapacitors system 10 can be charged at least enough to start the vehicle by charging the supercapacitors system 10 by way of an inlet charging station ICS on the side of the vehicle.

Each charge controller 31, 34, 12 should be based on the power (P=VI) of the energy generated by its voltage (V) and current (I). There should be a satisfactory voltage (V) for the controllers 31, 34, 12, and a current (I) with strength needed by a load, such as the vehicle accessories 35, the electrostatic motor 30 and the supercapacitors system 10 when being charged by the solar panel 11 and the wind powered system 20.

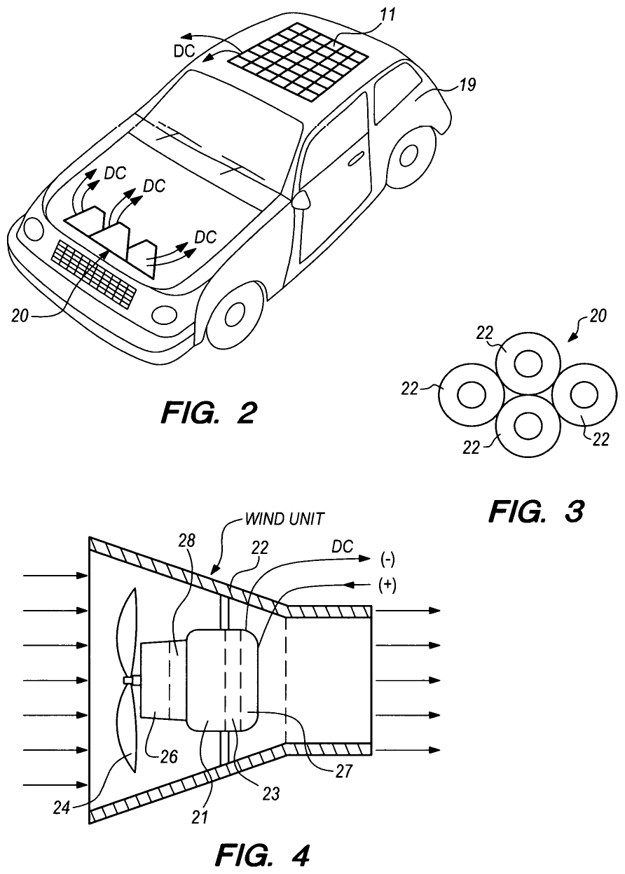

See FIG. 2. This vehicle is an automobile 19. The wind powered system 20 is mounted in the front of a vehicle, and the solar powered panel 11 is mounted top side of the vehicle. In FIG. 3, this is one arrangement of the housings 22 of the wind powered system 20; there are many others.

FIG. 4 is an enlarged, section view of a wind unit of the wind powered system 20. Inside the housing 22 is the wind blades 24, gearbox (transmission) 26, speed control 28, alternator 21, full-wave rectifier 23 and an electronic voltage regulator 27. One or more wind units can be used.

FIG. 5 is the beginning of the AC section for this VEHICLE ELECTROSTATIC REPULSION SYSTEM. The electrostatic repulsion motor 30 comprises a rotor 32 and its axle 32A, a stator 36, a main charging line 33 and a discharging line 37. Electrostatic motors rotate extremely fast.

A speed reducer 39 is sometimes needed. When the speed reducer 39 output axle 39A reduces the motor 30 output speed, but increases the output rotational force, this is important in many applications.

The reducer 39 is connected to a 3-phase, self- excited induction generator 40. The generator 40 is electrically connected to an AC motor controller 50. A rheostat 54 and accelerator pedal 58 combination is electrically connected to the controller 50 and control forces within it 50.

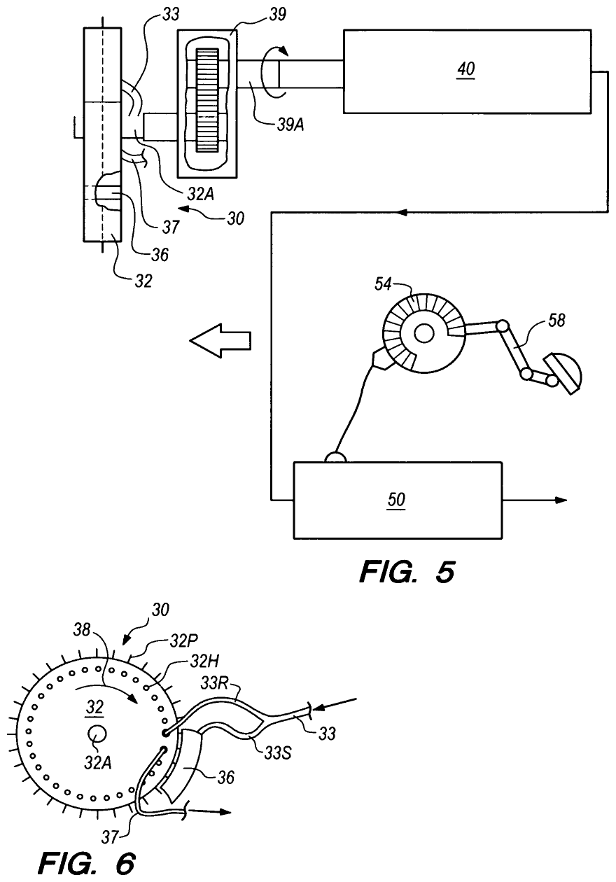

FIG. 6 is a side view of the electrostatic motor 30 comprising its rotor 32, stator 36, charging line 33 and discharging line 37. The main charging line 33 has a line 33R to the rotor 32 and a line 33S to the stator 36. The rotor 32 and stator 36 should be made from a material that is strong and is a good electrical insulator. The motor 30 axle 32A is metal.

The rotor 32 has equally spaced, metallic pointed prongs 32P around the circumference of its rim, adjacent each prong 32P is a side hole 32H. The rotor line 33R end do not touch the surface of the rotor 32. The line 33R charges each metallic, pointed prong 32P on the rim of the rotor 32, through its adjacent side hole 32H by electrical induction. The stator 36 has an inner metallic pointed prong within a hollow space (cavity). The pointed prong is connected to the line 33S that leads to the stator 36.

When a rotor 32 pointed prong 32P passes through a v-shaped groove in the stator 36. The prong 32P will later enter the hollow space of the stator 36, now the rotor prong 32P and the stator prong will be opposite each other. They now can be charged simultaneously by their electrical parallel lines 33, 33R, 33S. The two prongs will have like charges causing repulsion between them and rotation 38 of the rotor 32.

The rotor prong 32P would later be discharged by electrical induction into and through the end of the discharge line 37. A sequence of the rotor 32 metallic pointed prongs 32P passing through the stator 36, will cause continually rotation 38 of the rotor 32, when each is charged inside the hollow space (cavity) of the stator 36 and later discharged.

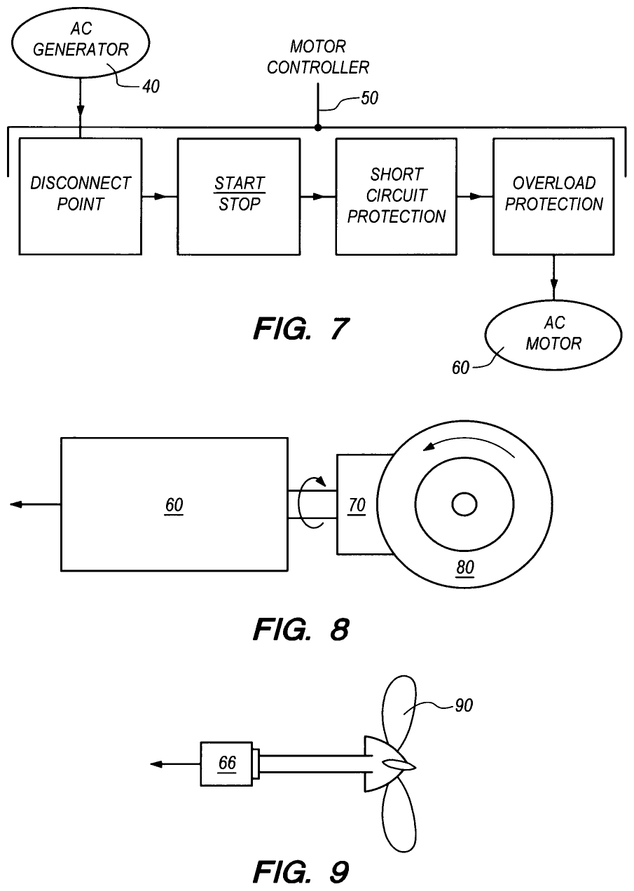

FIG. 7 shows all of the necessary functions of the motor controller 50. An AC induction motor 60 converts electric energy into mechanical energy, which can be used to turn vehicle wheels. This action is controlled by the motor controller 50, it receives a signal from the accelerator pedal 58 and then delivers the associated amount of power to the AC motor 60. The motor controller 50 should be able to reverse the AC motor 60 rotation giving the vehicle the ability to go in reverse.

FIG.8 shows the 3-phase induction motor 60 is connected to vehicle wheels 80 byway of a transmission 70. See FIG. 9, a submarine propeller 90 is connected to a 3-phase induction motor 66.

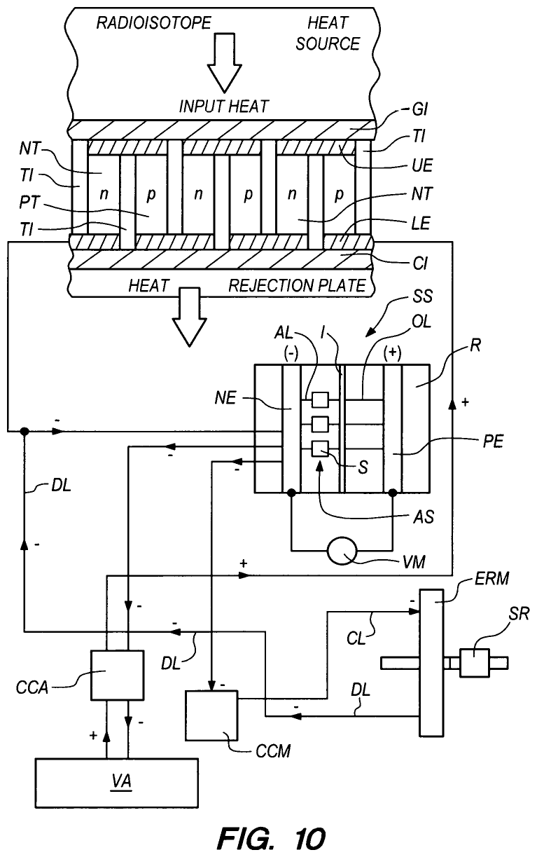

Refer to FIG. 10. A nuclear-powered battery: radioisotope thermoelectric generator is a source of energy. For powering a submarine underwater, a new source of energy is needed to charge a supercapacitors system SS.

A radioisotope heat source sends heat into a thermal conductor/electrical insulator (upper) CI; thermal/electrical conductor electrode (upper) UE (hot junction); thermal/electrical conductor electrode (lower) LE (cold junction), and another thermal conductor/electrical insulator (lower) CI. The center parts are thermal insulator TI, n-type thermoelement NT and the p-type thermoelement PT.

The supercapacitors system SS, an array of supercapacitors AS on one side of an insulator I, a line AL of a supercapacitor S is connected to and can be charged by negative electrode NE, and the other line OL of the supercapacitor S is passed through a hole in the insulator I and is connected to the positive electrode PE. The reservoir R is for temporary loose charges.

A voltmeter VM would measure this array of supercapacitors AS total voltage at all times. The supercapacitors system SS is connected to the thermal/electrical conductor electrode (lower) LE, a cold junction.

The negative electrode NE sends some of its charges through a charge controller CCA to the vehicle accessories VA. The negative electrode NE also sends some of its charges through a charge controller CCM to the electrostatic repulsion motor ERM. The motor ERM will have a charging line CL and a discharging line DL. And in some systems the motor ERM will have a speed reducer SR attached to its axle. The reducer SR is connected to the 3-phase, self-excited induction generator 40. See FIG. 5. For a submarine or ship, the accelerator pedal 58 can be replaced with manual controls.

Nearly 100% of the parts, devices and equipment needed for this VEHICLE ELECTROSTATIC PROPULSION SYSTEM can be found in various stores; todays' items are more compact and efficient with economical costs as well. The array of supercapacitors can replace the array of batteries used in present electric vehicles.

Claims: I claim:

1. A vehicle electrostatic propulsion system having a DC section with an electrostatic repulsion motor and a speed reducer connecting said DC section to an AC section, said propulsion system is powered by wind and solar energies, wherein:
said DC section has a supercapacitors system with an array of supercapacitors, each supercapacitor has an electric line connected to a negative electrode, and each said supercapacitor has another electric line passing through a hole in an insulator and is connected to a positive electrode;
said insulator is mounted between said two electrodes, with each said supercapacitor mounted on the side near said negative electrode;
said supercapacitors system is connected to a wind powered system comprising an array of wind units mounted in front of a vehicle an electric line connects said wind units of said wind powered system together;
another electric line connects said electric line of said wind powered system comprising said wind units, to said negative electrode of said supercapacitors system;
an electric line connects said negative electrode to a charge controller for the vehicle accessories, and another electric line is connected to said vehicle accessories from said charge controller. said supercapacitors system is connected to a solar panel mounted on top of said vehicle, said solar panel has an electric line to charge controller, and another electric line from said charge controller extending to said negative electrode of said supercapacitors system;
an electric line connects said negative electrode to a charge controller for said electrostatic repulsion motor, and an electric line to said motor from said charge controller is for charging said motor, a discharging electric line connects said motor back to said negative electrode and connected to axle of said motor is said speed reducer;
an electric line connects said induction generator to a motor controller having all of the necessary function for a disconnect point, start/stop functions, short circuit protection and overload protection; and
an electric line connects said motor controller to a 3-phase induction motor, said motor is mechanically connected to the vehicle wheels byway of transmission.

2. A vehicle electrostatic propulsion system having a DC section with an electrostatic repulsion motor connecting said DC section to an AC section, said propulsion system is powered by wind and solar energies, wherein:
said DC section has a supercapacitors system with an array of supercapacitors, each supercapacitor has an electric line connected to a negative electrode, and each said supercapacitor has another electric line passing through a hole in an insulator and is connected to a positive electrode;
said supercapacitorc system is connected to a wind powered system comprising a wind unit mounted in front of a vehicle;
another electric line connects said negative electrode to a charge controller for the vehicle accessories, and an electric line is connected to said vehicles accessories from said charge controller;
said supercapacitors system is connected to a solar panel mounted on top of said vehicle, said solar panel has an electric line to a charge controller, and another electric line from said charge controller extending to said negative electrode of said supercapacitors system;
an electric line connects said negative electrode to a charge controller for said electrostatic repulsion motor, and an electric line to said motor from said charge controller is for charging said motor, a discharging electric line connects said motor back to said negative electrode of said supercapacitors system;
an electric line connects said induction generator to a motor controller having all of the necessary functions such as a disconnect point, start/stop functions, short circuit protection and overload protection; and
an electric line connects said motor controller to manual controls for said vehicle, another electric line connects said motor controller to a 3-phase induction motor.

3. A vehicle electrostatic propulsion system having a DC section with an electrostatic repulsion motor connecting said DC section to an AC section, said propulsion system is powered by a nuclear-powered battery: radioisotope thermoelectric generator, wherein;
said DC section has a supercapacitor system with an array of supercapacitors, each supercapacitor has an electric line connected to a negative electrode, and each said supercapacitor has another electric line passing through a hole in an insulator and is connected to a positive electrode;
said insulator is mounted between said two electrodes, with each said supercapacitor is mounted on side of said insulator near said negative electrode;
said nuclear-powered battery: radioisotope thermoelectric generator is connected to said supercapacitors system by a negative electric line from said thermoelectric generator to said negative electrode of said supercapacitors system;
an electric line connects said negative electrode of said supercapacitors system to a charge controller for said electrostatic repulsion motor, and an electric line to said motor from said charge controller is for charging said motor, a discharging electric line connects said motor back to said negative electrode of said supercapacitors system; and
an electric line connects said motor controller to manual controls for said vehicle, another electric line connects said motor controller to a 3-phase induction motor, said motor is connected to a propeller of said vehicle.
